(19) United States
(12) Patent Application Publication
(10) Pub. No.: US 2022/0377266 A1
(43) Pub. Date: Nov. 24, 2022

(54) SOLID-STATE IMAGING DEVICE AND METHOD OF MANUFACTURING SOLID-STATE IMAGING DEVICE

(71) Applicant: SONY SEMICONDUCTOR SOLUTIONS CORPORATION, KANAGAWA (JP)

(72) Inventor: TAKAYUKI ENOMOTO, KUMAMOTO (JP)

(21) Appl. No.: 17/764,317

(22) PCT Filed: Sep. 24, 2020
(86) PCT No.: PCT/JP2020/035933

§ 371 Date: Mar. 28, 2022

(30) Foreign Application Priority Data
Oct. 7, 2019 (JP) 2019-184847

(51) Int. Cl. H04N 5/369; H01L 27/146; H01L 31/10

(52) U.S. Cl. CPC H04N 5/369; H01L 27/14601; H01L 31/10; G02B 1/11

(57) ABSTRACT

There are provided a solid-state imaging device capable of improving quantum efficiency while suppressing occurrence of color mixture, and a method of manufacturing such a solid-state imaging device. According to the present disclosure, a solid-state imaging device (100, 100a, 100b, 100c) is provided. The solid-state imaging device (100, 100a, 100b, 100c) includes a first region (4, 4a, 4b) and a second region (5, 5a) in a light receiving surface of an imaging pixel (1, 1a, 1b, 1c). The first region (4, 4a, 4b) is provided with unevenness. The second region (5, 5a) is provided with unevenness having a pitch narrower than that of the unevenness in the first region (4, 4a, 4b).

### FIELD

The present disclosure relates to a solid-state imaging device and a method of manufacturing a solid-state imaging device.

### BACKGROUND

There has been a solid-state imaging device in which unevenness is provided in a light receiving surface of an imaging pixel and a traveling direction of incident light is refracted by the unevenness, thereby increasing an optical path length of the incident light in a photoelectric conversion element to improve its quantum efficiency (see Patent Literature 1, for example).

### CITATION LIST

### Patent Literature

Patent Literature 1: JP 2018-088532 A

### SUMMARY

### Technical Problem

However, in the solid-state imaging device, when the pitch of the unevenness provided in the light receiving surface is large, the incident light refracted at the light receiving surface may enter an adjacent imaging pixel to cause color mixture. On the other hand, when the pitch of the unevenness is small, quantum efficiency is not improved.

In view of this, the present disclosure proposes a solid-state imaging device capable of improving quantum efficiency while suppressing occurrence of color mixture, and a method of manufacturing such a solid-state imaging device.

### Solution to Problem

According to the present disclosure, a solid-state imaging device is provided. The solid-state imaging device includes a first region and a second region in a light receiving surface of an imaging pixel. The first region is provided with unevenness. The second region is provided with unevenness having a pitch narrower than that of the unevenness in the first region.

### BRIEF DESCRIPTION OF DRAWINGS

FIG. 1 is an explanatory cross-sectional view of an imaging pixel of a solid-state imaging device according to the present disclosure.

FIG. 2 is a plan view of the imaging pixel of the solid-state imaging device according to the present disclosure.

FIG. 3A is an explanatory view illustrating a manufacturing process of the solid-state imaging device according to the present disclosure.

FIG. 3B is an explanatory view illustrating a manufacturing process of the solid-state imaging device according to the present disclosure.

FIG. 3C is an explanatory view illustrating a manufacturing process of the solid-state imaging device according to the present disclosure.

FIG. 4A is an explanatory view illustrating a manufacturing process of the solid-state imaging device according to the present disclosure.

FIG. 4B is an explanatory view illustrating a manufacturing process of the solid-state imaging device according to the present disclosure.

FIG. 4C is an explanatory view illustrating a manufacturing process of the solid-state imaging device according to the present disclosure.

FIG. 5A is an explanatory view illustrating a manufacturing process of the solid-state imaging device according to the present disclosure.

FIG. 5B is an explanatory view illustrating a manufacturing process of the solid-state imaging device according to the present disclosure.

FIG. 5C is an explanatory view illustrating a manufacturing process of the solid-state imaging device according to the present disclosure.

FIG. 6A is an explanatory view illustrating a manufacturing process of the solid-state imaging device according to the present disclosure.

FIG. 6B is an explanatory view illustrating a manufacturing process of the solid-state imaging device according to the present disclosure.

FIG. 7 is an explanatory cross-sectional view of an imaging pixel of a solid-state imaging device according to a first modification of the present disclosure.

FIG. 8 is an explanatory cross-sectional view of an imaging pixel of a solid-state imaging device according to a second modification of the present disclosure.

FIG. 9 is an explanatory cross-sectional view of an imaging pixel of a solid-state imaging device according to a third modification of the present disclosure.

FIG. 10 is a plan view illustrating a first arrangement example of a first region and a second region according to the present disclosure.

FIG. 11 is a plan view illustrating a second arrangement example of the first region and the second region according to the present disclosure.

FIG. 12 is a plan view illustrating a third arrangement example of the first region and the second region according to the present disclosure.

FIG. 13 is a plan view illustrating a fourth arrangement example of the first region and the second region according to the present disclosure.

### DESCRIPTION OF EMBODIMENTS

Hereinafter, embodiments of the present disclosure will be described in detail with reference to the drawings. In each of the following embodiments, the same parts are denoted by the same reference numerals, and duplicated description will be omitted.

### [1. Configuration of Solid-State Imaging Device]

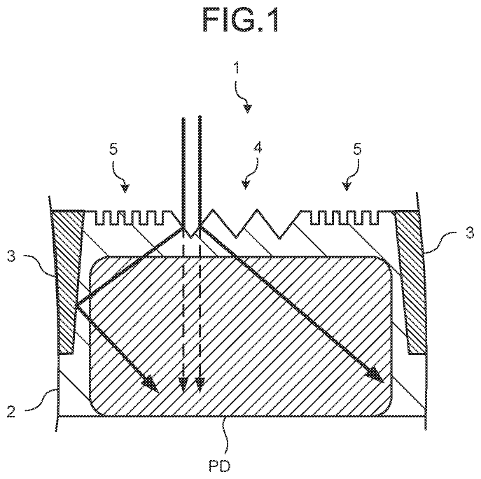

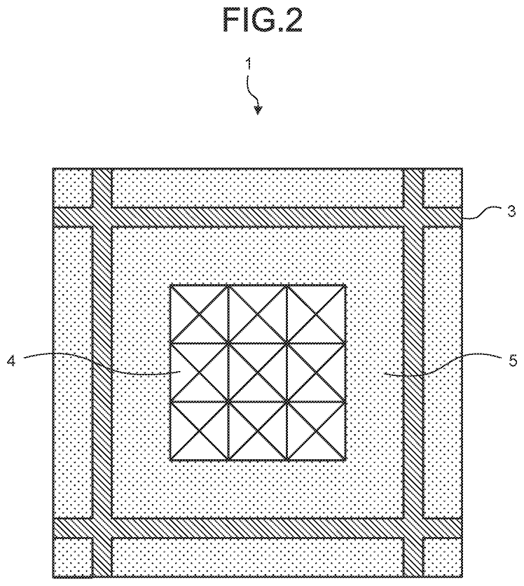

First, a configuration of a solid-state imaging device according to the present disclosure will be described with reference to FIGS. 1 and 2. FIG. 1 is an explanatory cross-sectional view of an imaging pixel 1 of the solid-state imaging device according to the present disclosure. FIG. 2 is a plan view of the imaging pixel 1 of the solid-state imaging device according to the present disclosure.

FIGS. 1 and 2 selectively illustrate a part corresponding to one pixel among a plurality of two-dimensionally arranged imaging pixels included in the solid-state imaging device. Further, in FIG. 1, illustration of a color filter and a microlens provided on a light receiving surface of the imaging pixel 1 is omitted.

As illustrated in FIG. 1, the imaging pixel 1 according to the present disclosure includes a photoelectric conversion element PD provided in a semiconductor substrate 2 such as a silicon (Si) substrate, for example. The photoelectric conversion element PD converts incident light into signal charges that depend on the amount of received light.

Further, the imaging pixel 1 includes a deep trench isolation (DTI) 3 having a light shielding property between the imaging pixel 1 and an adjacent imaging pixel. The DTI 3 includes an aluminum oxide film formed on an inner surface of a trench formed between adjacent imaging pixels, an insulator embedded in the trench having the aluminum oxide film formed thereon, and a light shielding film embedded in the insulator and formed of a metal having a light shielding property. As a result, the imaging pixel 1 can suppress occurrence of color mixture caused due to entry of incident light into its adjacent imaging pixel.

In addition, a negative fixed charge film (pinning film) may be provided on a side wall of the DTI 3. The pinning film is formed using, for example, hafnium oxide (Hf₂). The pinning film may be formed using zirconium dioxide (ZrO₂), tantalum oxide (Ta₂O₅), or the like.

Then, the imaging pixel 1 includes a first region 4 provided with unevenness and a second region 5 provided with unevenness having a pitch narrower than that of the unevenness of the first region 4, in the light receiving surface. The unevenness in the first region 4 has a relatively large pitch of 100 nm, preferably from 350 to 650 nm. The depth of a recess in the unevenness in the first region 4 is from 250 to 260 nm.

The recess in the unevenness in the first region 4 has a V-shape in cross section in which the width becomes narrower toward a deeper position. As a result, as indicated by a thick solid arrow in FIG. 1, light incident on the imaging pixel is largely refracted at the side surface of the recess of the first region 4, and is incident on the photoelectric conversion element PD from an oblique direction.

Therefore, in the imaging pixel 1, as compared to an optical path length of incident light that perpendicularly enters the light receiving surface as indicated by a dotted arrow in a case where no unevenness is provided in the light receiving surface, for example, the optical path length of incident light in the photoelectric conversion element PD can be made longer, so that the quantum efficiency of the photoelectric conversion element PD can be improved.

In the unevenness of the first region 4, a region occupied by air is larger than a region occupied by Si of the semiconductor substrate 2 in a shallow portion of the recess. On the other hand, the region occupied by Si becomes larger toward a deeper position in the recess, so that a refractive index is steplessly changed there. Thus, the unevenness serves as a pseudo antireflection film. As a result, the imaging pixel 1 can improve its light receiving sensitivity.

However, in a case where the unevenness of the first region 4 is provided throughout the light receiving surface of the imaging pixel 1, light that is incident from the outer edge of the light receiving region and is refracted may enter an adjacent imaging pixel to cause color mixture. Because of this, as illustrated in FIG. 2, the first region 4 is provided at the center of the light receiving surface in the imaging pixel 1, and is not provided at the outer edge of the light receiving surface.

As a result, the imaging pixel 1 can prevent light incident from the outer edge of the light receiving surface from being largely refracted and entering into its adjacent imaging pixel, thereby suppressing occurrence of color mixture. However, in the imaging pixel 1, in a case where no unevenness is provided in the outer edge of the light receiving surface, the antireflection performance in the outer edge is degraded, causing degradation of the quantum efficiency.

Then, the imaging pixel 1 includes the second region 5 provided with the unevenness having a pitch narrower than that of the unevenness of the first region 4. The second region 5 is provided so as to surround the periphery of the first region 4 in the light receiving surface. The unevenness in the second region 5 has a pitch and a depth of 10 to 30 nm.

As described above, the unevenness of the second region 5 has a pitch that is much narrower (smaller) than that of the unevenness of the first region 4. This prevents incident light from being largely refracted. As a result, the imaging pixel 1 can prevent light incident from the outer edge of the light receiving surface from being largely refracted and entering into its adjacent imaging pixel, thereby suppressing occurrence of color mixture.

In addition, the unevenness in the second region 5 serves as a pseudo antireflection film similarly to the unevenness in the first region 4. When the pitch and the depth of the unevenness in the second region 5 are 10 to 30 nm as described above, the pseudo refractive index is 2.5, which is higher than the refractive index (1.4) of a layered antireflection film such as SiO2 (silicon oxide), thereby achieving a refractive index close to the refractive index (3.9) of Si.

That is, the unevenness in the second region 5 has higher antireflection performance than that of a layered antireflection film of SiO2 or the like in a visible light region. As a result, the imaging pixel 1 can improve the quantum efficiency also for light incident from the outer edge of the light receiving surface.

As described above, the imaging pixel 1 includes the first region 4 provided with the unevenness and the second region 5 provided with the unevenness having a pitch narrower than that of the unevenness of the first region 4, in the light receiving surface. Therefore, the solid-state imaging device including the imaging pixel 1 can improve the quantum efficiency while suppressing occurrence of color mixture.

### [2. Method of Manufacturing Solid-State Imaging Device]

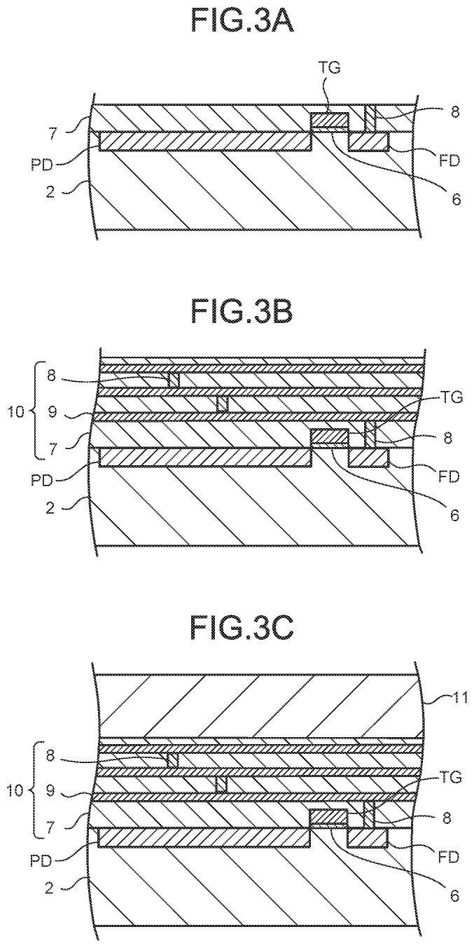

Next, a method of manufacturing the solid-state imaging device according to the present disclosure will be described with reference to FIGS. 3A to 6B. FIGS. 3A to 6B are explanatory views illustrating manufacturing processes of the solid-state imaging device according to the present disclosure. Here, processes of forming the imaging pixel 1 will be described. Since a process of forming the DTI 3 is a known technique, the description thereof is omitted here.

To form the imaging pixel 1, first, as illustrated in FIG. 3A, a semiconductor substrate 2 doped with a P-type impurity such as boron (B), for example, is prepared. Then, an N-type impurity such as phosphorus (P) is ion-implanted into a predetermined region inside the semiconductor substrate 2 from the front-surface side (upper-surface side in the figure) of the semiconductor substrate 2, and an annealing treatment is performed, thereby forming the photoelectric conversion element PD and a floating diffusion FD.

Subsequently, a gate insulating film 6 is formed of SiO2, for example, in a region between the photoelectric conversion element PD and the floating diffusion FD on the upper surface of the semiconductor substrate 2, and a transfer gate TG is formed of polysilicon, for example, on the gate insulating film 6.

As a result, there is formed a transfer transistor that transfers signal charges photoelectrically converted by the photoelectric conversion element PD, to the floating diffusion FD. At that time, a reset transistor, an amplifier transistor, and a vertical selection transistor of each imaging pixel 1 are formed by a similar manufacturing method.

Thereafter, an interlayer insulating film 7 is formed of tetraethoxysilane (TEOS), for example, on the semiconductor substrate 2, and a contact hole reaching the floating diffusion FD from the upper surface of the interlayer insulating film 7 is formed. Then, the contact hole is filled with metal to form a contact via 8.

Subsequently, as illustrated in FIG. 3B, on the formed interlayer insulating film 7, a process of forming a wiring layer 9 in which a predetermined circuit pattern is formed of copper (Cu),for example, the interlayer insulating film 7, and the contact via 8 is repeated to form a multilayer wiring layer 10.

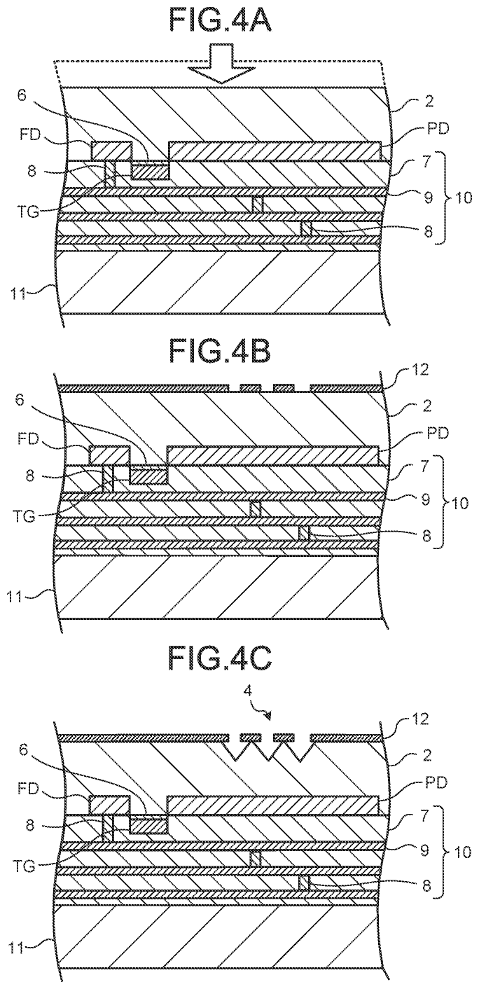

Subsequently, as illustrated in FIG. 3C, a support substrate 11 such as a Si substrate, for example, is bonded onto the multilayer wiring layer 10. Then, as illustrated in FIG. 4A, the top and bottom of the structure illustrated in FIG. 3C are reversed, and the semiconductor substrate 2 is ground and polished from the back-surface side by chemical mechanical polishing (CMP), dry etching, and wet etching, for example, to have a desired thickness.

Subsequently, as illustrated in FIG. 4B, a protective film 12 is formed of SiO2, Si3N4 (silicon nitride), or the like, for example, on the back surface of the semiconductor substrate 2. Then, a photoresist (not illustrated) is applied onto the protective film 12, patterning is performed by photolithography, and etching is performed using the photoresist as a mask. This results in formation of a plurality of openings at positions on the center of the photoelectric conversion element PD in the protective film 12.

Subsequently, as illustrated in FIG. 4C, isotropic etching or anisotropic etching for obtaining a predetermined slope is performed to form unevenness at the center of a light receiving region in the back surface of the semiconductor substrate 2, thereby forming the first region 4.

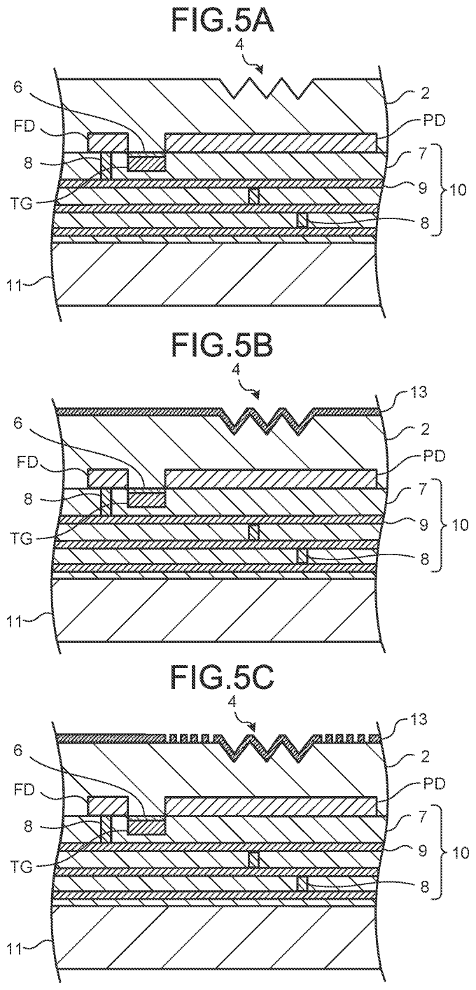

Subsequently, as illustrated in FIG. 5A, the protective film 12 is peeled off, and thereafter, as illustrated in FIG. 5B, a protective film 13 is formed of SiO2, Si3N4, or the like, for example, on the back surface of the semiconductor substrate 2. Then, a photoresist (not illustrated) is applied onto the protective film 13, and patterning is performed by photolithography.

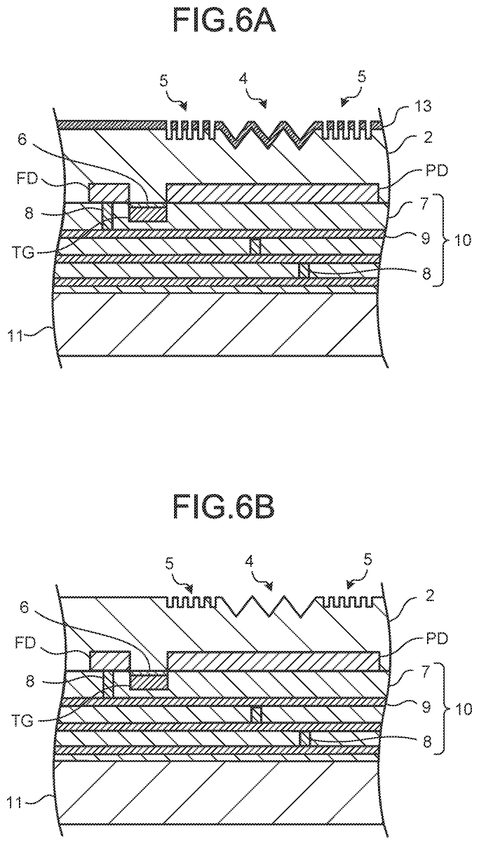

Subsequently, as illustrated in FIG. 5C, etching is performed using the photoresist as a mask to form a plurality of openings in a region surrounding the first region 4 in the protective film 13. Then, as illustrated in FIG. 6A, isotropic etching or anisotropic etching for obtaining a predetermined slope is performed to form unevenness having a pitch narrower than that of the unevenness of the first region 4 in a region surrounding the first region 4 in the back surface of the semiconductor substrate 2, thereby forming the second region 5.

Subsequently, as illustrated in FIG. 6B, the protective film 13 is removed, and thus, the first region 4 provided with the unevenness and the second region 5 provided with the unevenness having a pitch narrower than that of the unevenness of the first region 4 are formed in the light receiving surface of the imaging pixel 1. Thereafter, a light guide layer, a color filter, and a microlens are sequentially formed on the light receiving surface of the semiconductor substrate 2 to complete the imaging pixel 1.

Though not illustrated in the drawings, in the imaging pixel 1, a negative fixed charge film (pinning film) may be provided on the light receiving surface of the semiconductor substrate 2. The pinning film is formed using, for example, hafnium oxide (Hf₂). The pinning film may be formed using zirconium dioxide (ZrO₂), tantalum oxide (Ta₂O₅), or the like.

As a result, in the imaging pixel 1, electrons existing in the photoelectric conversion element PD independently of incident light are caused to be combined with holes included in the negative fixed charge film, so that occurrence of a white flaw can be suppressed.

### [3. Modifications]

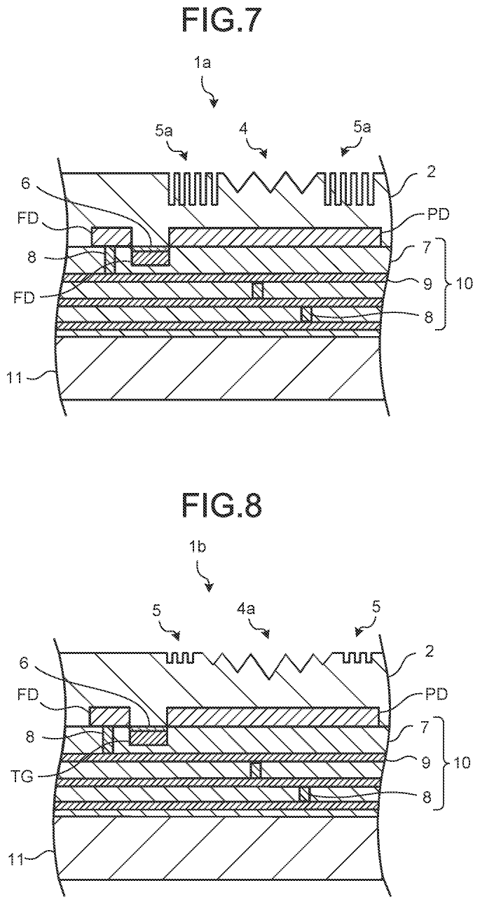

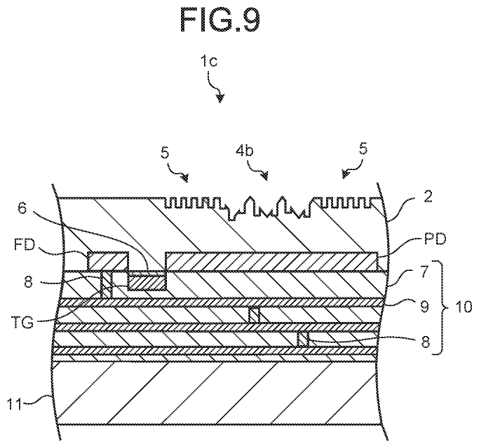

Next, modifications of the imaging pixel according to the present disclosure will be described with reference to FIGS. 7 to 9. FIG. 7 is an explanatory cross-sectional view of an imaging pixel of a solid-state imaging device according to a first modification of the present disclosure. FIG. 8 is an explanatory cross-sectional view of an imaging pixel of a solid-state imaging device according to a second modification of the present disclosure. FIG. 9 is an explanatory cross-sectional view of an imaging pixel of a solid-state imaging device according to a third modification of the present disclosure.

Hereinafter, the same components as those illustrated in FIG. 6B are denoted by the same reference numerals as those illustrated in FIG. 6B, and duplicated description will be omitted. As illustrated in FIG. 7, in an imaging pixel 1a according to the first modification, the depth of a recess of unevenness in a second region 5a is larger than the depth of a recess of the unevenness in the first region 4.

As a result, in the imaging pixel 1a, the second region 5a that functions as a pseudo antireflection film having refractive index that is steplessly changed as the depth in the depth direction of the semiconductor substrate 2 increases, has a greater thickness, to have a refractive index close to the refractive index of the semiconductor substrate 2. Thus, in the imaging pixel 1a, the antireflection performance of the second region 5a is improved, so that the light receiving sensitivity can be further improved.

Besides, as illustrated in FIG. 8, the pitch of the unevenness in a first region 4a of an imaging pixel 1b according to the second modification decreases from the center toward the outer edge in the first region 4a. As a result, in the imaging pixel 1b, the unevenness becomes more moderate as a distance from the center in the first region 4a increases toward the outer edge. Thus, the imaging pixel 1b can more reliably suppress occurrence of color mixture caused due to entry of incident light refracted by the unevenness of the first region 4a into its adjacent imaging pixel.

Besides, as illustrated in FIG. 9, unevenness in a first region 4b of an imaging pixel 1c according to the third modification is further provided with additional unevenness having a pitch narrower than the pitch of the unevenness, on the slope of the unevenness. As a result, in the imaging pixel 1c, the antireflection performance of the first region 4b is further improved by the principles similar to the principles of improving the antireflection performance of the second region 5, so that the light receiving sensitivity to incident light can be further enhanced.

### [4. Arrangement Example of First Region and Second Region]

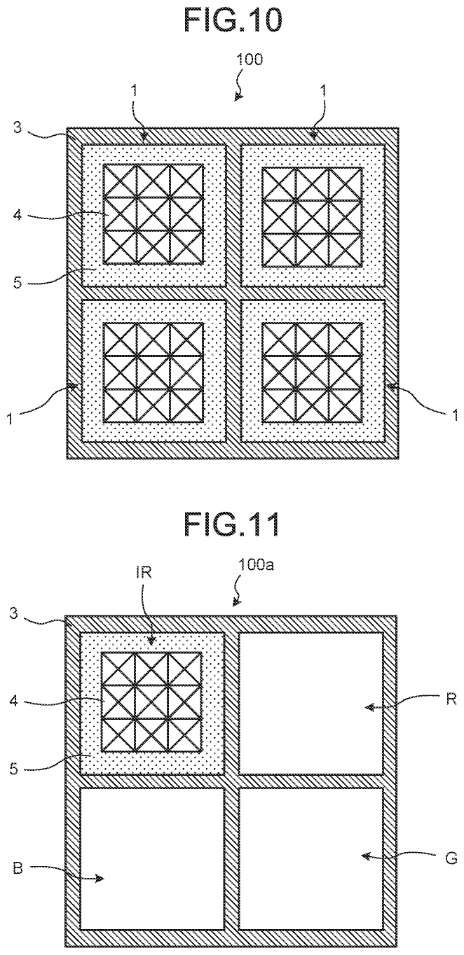

Next, arrangement examples of the first region 4 and the second region 5 according to the present disclosure will be described with reference to FIGS. 10 to 13. FIG. 10 is a plan view illustrating a first arrangement example of the first region 4 and the second region 5 according to the present disclosure. FIG. 11 is a plan view illustrating a second arrangement example of the first region 4 and the second region 5 according to the present disclosure.

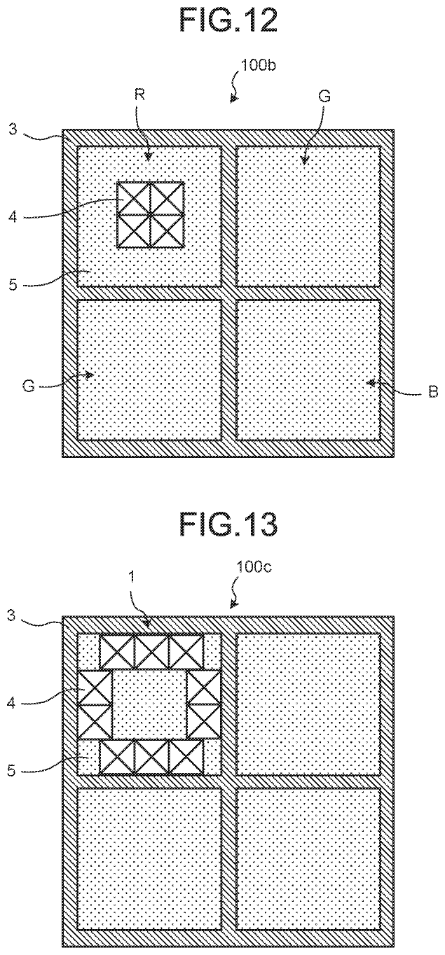

FIG. 12 is a plan view illustrating a third arrangement example of the first region 4 and the second region 5 according to the present disclosure. FIG. 13 is a plan view illustrating a fourth arrangement example of the first region 4 and the second region 5 according to the present disclosure. FIGS. 10 to 13 selectively illustrate a part corresponding to four pixels among a plurality of imaging pixels included in the solid-state imaging device.

As illustrated in FIG. 10, in a solid-state imaging device 100, the first region 4 and the second region 5 are provided in each of all the imaging pixels 1. The first region 4 is provided at the center of each imaging pixel 1. The second region 5 is provided so as to surround the periphery of the first region 4. Therefore, the solid-state imaging device 100 can improve the quantum efficiency while suppressing occurrence of color mixture, for each of all the imaging pixels 1.

Besides, as illustrated in FIG. 11, a solid-state imaging device 100a includes an imaging pixel R that detects red light, an imaging pixel G that detects green light, an imaging pixel B that detects blue light, and an imaging pixel IR that detects infrared light.

Infrared light has lower luminance than red light, green light, and blue light. Thus, the imaging pixel IR that detects infrared light needs to have higher quantum efficiency than the other imaging pixels R, G, and B. Then, in the solid-state imaging device 100a, the first region 4 and the second region 5 are provided in the imaging pixel IR that detects infrared light, and the first region 4 and the second region 5 are not provided in the other imaging pixels R, G, and B.

In this manner, the first region 4 and the second region 5 are provided in the light receiving surface of at least one imaging pixel (the imaging pixel IR, for example) or more among the plurality of imaging pixels IR, R, G, and B arranged two-dimensionally.

As a result, the solid-state imaging device 100a can improve the quantum efficiency of the imaging pixel IR that detects infrared light by including the first region 4 and the second region 5 in the imaging pixel IR that detects infrared light, for example.

Besides, as illustrated in FIG. 12, a solid-state imaging device 100b includes the imaging pixel R that detects red light, the imaging pixel G that detects green light, and the imaging pixel B that detects blue light. Red light has lower luminance than green light and blue light.

Then, in the solid-state imaging device 100b, for improving the antireflection performance required for all of the imaging pixels R, G, and B, the second region 5 is provided in each of all the imaging pixels R, G, and B, and the first region 4 is provided in the imaging pixel R that particularly needs to be improved in quantum efficiency.

In this manner, the first region 4 and the second region 5 are provided in the light receiving surfaces of the imaging pixels R and IR that detect light having a long wavelength equal to or longer than the wavelength of red light. As a result, the quantum efficiency of the imaging pixels R and IR that detect light having a long wavelength equal to or longer than the wavelength of red light can be improved, and the quantum efficiency can be made close to the quantum efficiency of the other imaging pixels R, G, and B.

Meanwhile, as seen in a solid-state imaging device 100c illustrated in FIG. 14, the first region 4 may be provided annularly in plan view along the outer edge of the light receiving surface of the imaging pixel 1. In such a configuration, the second region 5 is provided in a region where the first region 4 is not provided in the light receiving surface of the imaging pixel 1.

With the solid-state imaging device 100c, an optical path length in the photoelectric conversion element PD is lengthened because of inclusion of the first region 4, so that the quantum efficiency can be improved. It is also possible to suppress occurrence of color mixture as compared with the case where the first region 4 is provided throughout the light receiving surface.

Additionally, the solid-state imaging devices 100, 100a, 100b, and 100c illustrated in FIGS. 10 to 13 may be provided with the first region 4a illustrated in FIG. 8 or the first region 4b illustrated in FIG. 9, in place of the first region 4. Further, in the solid-state imaging devices 100, 100a, 100b, and 100c, the second region 5a illustrated in FIG. 7 may be provided in place of the second region 5. Also with the above-described configurations, the solid-state imaging devices 100, 100a, 100b, and 100c can improve the quantum efficiency while suppressing occurrence of color mixture.

Moreover, in the above-described embodiments, the description has been made about the case where the first region 4 and the second region 5 are provided in the light receiving surface of the semiconductor substrate 2. However, in a case where an insulating film is stacked on the light receiving surface of the semiconductor substrate 2, the first region 4 and the second region 5 may be provided in a light receiving surface of the insulating layer.

More specifically, the imaging pixel 1 may include the first region 4 provided with the unevenness having a relatively large pitch at the center of the light receiving surface of the insulating film stacked on the semiconductor substrate 2, and the second region 5 provided with the unevenness having a pitch narrower than that of the unevenness in the first region. Also with the above-described configurations, the imaging pixel 1 can improve the quantum efficiency while suppressing occurrence of color mixture.

### [5. Effects]

The solid-state imaging device 100 includes the first region 4 and the second region 5 in the light receiving surface of the imaging pixel 1. The first region 4 is provided with unevenness. The second region 5 is provided with unevenness having a pitch narrower than that of the unevenness in the first region 4. Thus, the solid-state imaging device 100 can improve the quantum efficiency while suppressing occurrence of color mixture.

Further, the first region 4 and the second region 5 are provided in the light receiving surface of the insulating film stacked on the semiconductor substrate 2 including the photoelectric conversion element PD. Thus, the solid-state imaging device 100 can improve the quantum efficiency while suppressing occurrence of color mixture in the case where the insulating film is stacked on the semiconductor substrate 2.

Further, the first region 4 and the second region 5 are provided in the light receiving surface of the semiconductor substrate 2 including the photoelectric conversion element PD. Thus, the solid-state imaging device 100 can improve the antireflection performance without including an antireflection film on the light receiving surface of the imaging pixel, and can improve the quantum efficiency while suppressing occurrence of color mixture.

Further, the solid-state imaging device 100 includes a negative fixed charge film on the light receiving surface of the semiconductor substrate 2. Thus, in the solid-state imaging device 100, electrons existing in the photoelectric conversion element PD independently of incident light are caused to be combined with holes included in the negative fixed charge film, so that occurrence of a white flaw can be suppressed.

Further, the solid-state imaging device 100 includes the DTI having a light shielding property between adjacent imaging pixels. Thus, the solid-state imaging device 100 can suppress occurrence of color mixture caused due to entry of incident light into an adjacent imaging pixel.

Further, the first region 4 and the second region 5 are provided in the light receiving surface of at least one imaging pixel or more among the plurality of imaging pixels arranged two-dimensionally. Thus, in the solid-state imaging device 100a, the first region 4 and the second region 5 are provided in the imaging pixel that detects light of a color having relatively low luminance, so that the quantum efficiency of the imaging pixel that detects light of a color having low luminance can be made close to the quantum efficiency of the imaging pixel that detects light of another color.

The first region 4 and the second region 5 are provided in the light receiving surface of the imaging pixel 1 that detects light having a wavelength longer than the wavelength of red light. Thus, in the solid-state imaging devices 100a and 100b, the first region 4 and the second region 5 are provided in the imaging pixel IR that detects red light or infrared light, for example, so that the quantum efficiency of the imaging pixels R and IR that detect red light or infrared light can be improved.

In addition, the recess of the unevenness in the first region 4 becomes narrower toward a deeper position. Thus, the solid-state imaging device 100 can efficiently refract incident light to lengthen the optical path length in the photoelectric conversion element PD, thereby improving the quantum efficiency.

Further, the first region 4 is provided at the center of the light receiving surface in the imaging pixel 1. The second region 5 is provided so as to surround the periphery of the first region 4. Thus, the solid-state imaging device 100 can improve the antireflection performance of the imaging pixel 1 while suppressing occurrence of color mixture caused due to incident light refracted and diffracted by the unevenness in the first region 4.

Further, the pitch of the unevenness in the first region 4 decreases from the center toward the outer edge in the first region. Thus, the solid-state imaging device 100 can more reliably suppress occurrence of color mixture.

Further, the unevenness in the first region 4 includes additional unevenness having a pitch narrower than the pitch of the unevenness on the slope of the unevenness. Thus, the imaging pixel 1c can further improve the antireflection performance in the first region 4b.

Further, the recess of the unevenness in the second region 5 has a depth smaller than the depth of the recess of the unevenness in the first region 4. Thus, the recess of the unevenness in the second region 5 can be formed in a relatively short time.

Further, the recess of the unevenness in the second region 5a has a depth larger than the depth of the recess of the unevenness in the first region 4. As a result, in the imaging pixel 1a, the second region 5a that functions as a pseudo antireflection film having refractive index that is steplessly changed as the depth in the depth direction of the semiconductor substrate 2 increases, has a greater thickness, to have a refractive index close to the refractive index of the semiconductor substrate 2. Thus, in the imaging pixel 1a, the antireflection performance of the second region 5a is improved, so that the light receiving sensitivity can be further improved.

A method of manufacturing a solid-state imaging device includes forming unevenness in a first region in a light receiving surface of an imaging pixel, and forming unevenness having a pitch narrower than that of the unevenness in the first region, in a second region in the light receiving surface. This makes it possible to manufacture a solid-state imaging device capable of improving the quantum efficiency while suppressing occurrence of color mixture.

Additionally, the effects described in the present specification are mere examples and are not limited, and other effects may be produced.

Moreover, the present technique can also have the following configurations.

(1)

A solid-state imaging device including:
in a light receiving surface of an imaging pixel,
a first region provided with unevenness; and
a second region provided with unevenness having a pitch narrower than a pitch of the unevenness in the first region.
   (2)

The solid-state imaging device according to (1), wherein
the first region and the second region are
provided in a light receiving surface of an insulating film stacked on a semiconductor substrate including a photoelectric conversion element.
   (3)

The solid-state imaging device according to (1), wherein
the first region and the second region are
provided in a light receiving surface of a semiconductor substrate including a photoelectric conversion element.
   (4)

The solid-state imaging device according to (3), further including
a negative fixed charge film on the light receiving surface of the semiconductor substrate.
   (5)

The solid-state imaging device according to any one of (1) to (4), further including
a deep trench isolation (DTI) having a light shielding property between the imaging pixel and an adjacent imaging pixel.
   (6)

The solid-state imaging device according to any one of (1) to (5), wherein
the first region and the second region are
provided in the light receiving surface of at least one imaging pixel or more among a plurality of the imaging pixels arranged two-dimensionally.
   (7)

The solid-state imaging device according to any one of (1) to (6), wherein
the first region and the second region are
provided in the light receiving surface of the imaging pixel that detects light having a long wavelength equal to or longer than a wavelength of red light.
   (8)

The solid-state imaging device according to any one of (1) to (7), wherein
a recess of the unevenness in the first region
becomes narrower toward a deeper position. (9)

The solid-state imaging device according any one of (1) to (8), wherein
the first region is
provided at a center of the light receiving surface in the imaging pixel, and
the second region is
provided so as to surround a periphery of the first region.
   (10)

The solid-state imaging device according to (9), wherein
the pitch of the unevenness in the first region
decreases from the center toward an outer edge in the first region.
   (11)

The solid-state imaging device according to (9) or (10), wherein
the unevenness in the first region includes
additional unevenness having a pitch narrower than the pitch of the unevenness on a slope of the unevenness.
   (12)

The solid-state imaging device according to any one of (1) to (11), wherein
a recess of the unevenness in the second region has
a depth smaller than a depth of a recess of the unevenness in the first region.
   (13)

The solid-state imaging device according to any one of (1) to (11), wherein
a recess of the unevenness in the second region has
a depth larger than a depth of a recess of the unevenness in the first region.

14. A method of manufacturing a solid-state imaging device, including:
forming unevenness in a first region in a light receiving surface of an imaging pixel; and
forming unevenness having a pitch narrower than a pitch of the unevenness in the first region, in a second region in the light receiving surface.

### REFERENCE SIGNS LIST

100, 100a, 100b, 100c SOLID-STATE IMAGING DEVICE

1, 1a, 1b, 1c IMAGING PIXEL

2 SEMICONDUCTOR SUBSTRATE

3 DTI

4, 4a, 4b FIRST REGION

5, 5a SECOND REGION

6 GATE INSULATING FILM

7 INTERLAYER INSULATING FILM

8 CONTACT VIA

9 WIRING LAYER

10 MULTILAYER WIRING LAYER

11 SUPPORT SUBSTRATE

12, 13 PROTECTIVE FILM

PD PHOTOELECTRIC CONVERSION ELEMENT

FD FLOATING DIFFUSION

TG TRANSFER GATE

1. A solid-state imaging device comprising:
in a light receiving surface of an imaging pixel,
a first region provided with unevenness; and
a second region provided with unevenness having a pitch narrower than a pitch of the unevenness in the first region.

2. The solid-state imaging device according to claim 1, wherein
the first region and the second region are
provided in a light receiving surface of an insulating film stacked on a semiconductor substrate including a photoelectric conversion element.

3. The solid-state imaging device according to claim 1, wherein
the first region and the second region are
provided in a light receiving surface of a semiconductor substrate including a photoelectric conversion element.

4. The solid-state imaging device according to claim 3, further comprising
a negative fixed charge film on the light receiving surface of the semiconductor substrate.

5. The solid-state imaging device according to claim 1, further comprising
a deep trench isolation (DTI) having a light shielding property between the imaging pixel and an adjacent imaging pixel.

6. The solid-state imaging device according to claim 1, wherein
the first region and the second region are
provided in the light receiving surface of at least one imaging pixel or more among a plurality of the imaging pixels arranged two-dimensionally.

7. The solid-state imaging device according to claim 1, wherein
the first region and the second region are
provided in the light receiving surface of the imaging pixel that detects light having a long wavelength equal to or longer than a wavelength of red light.

8. The solid-state imaging device according to claim 1, wherein
a recess of the unevenness in the first region
becomes narrower toward a deeper position.

9. The solid-state imaging device according to claim 1, wherein
the first region is
provided at a center of the light receiving surface in the imaging pixel, and
the second region is
provided so as to surround a periphery of the first region.

10. The solid-state imaging device according to claim 9, wherein
the pitch of the unevenness in the first region
decreases from the center toward an outer edge in the first region.

11. The solid-state imaging device according to claim 9, wherein
the unevenness in the first region includes
additional unevenness having a pitch narrower than the pitch of the unevenness on a slope of the unevenness.

12. The solid-state imaging device according to claim 1, wherein
a recess of the unevenness in the second region has
a depth smaller than a depth of a recess of the unevenness in the first region.

13. The solid-state imaging device according to claim 1, wherein
a recess of the unevenness in the second region has
a depth larger than a depth of a recess of the unevenness in the first region.

14. A method of manufacturing a solid-state imaging device, comprising:
forming unevenness in a first region in a light receiving surface of an imaging pixel; and
forming unevenness having a pitch narrower than a pitch of the unevenness in the first region, in a second region in the light receiving surface.
